(19) United States
(12) Patent Application Publication
(10) Pub. No.: US 2026/0121603 A1
(43) Pub. Date: Apr. 30, 2026

(54) VARIABLE GAIN AMPLIFICATION DEVICE AND TWO-INPUT AMPLIFICATION DEVICE

(71) Applicant: Mitsubishi Electric Corporation, Tokyo (JP)

(72) Inventors: Wataru YAMAMOTO, Tokyo (JP); Akihito Hirai, Tokyo (JP); Koji Tsutsumi, Tokyo (JP)

(73) Assignee: Mitsubishi Electric Corporation, Tokyo (JP)

(21) Appl. No.: 19/420,271

(22) Filed: Dec. 15, 2025

Related U.S. Application Data
(63) Continuation of application No. PCT/JP2023/025807, filed on Jul. 13, 2023.

(51) Int. Cl. H03G 3/30

(52) U.S. Cl. CPC H03G 3/30

(57) ABSTRACT

A variable gain amplification device includes: a splitter to split a target signal into first and second signals; a first variable gain amplifier to amplify the first signal in accordance with first characteristics, and output the first signal amplified to a first amplification element, the first variable gain amplifier having the first characteristics whose gain corresponding to a control signal indicating an envelope magnitude of the target signal is expressed by a first sigmoid function; and a second variable gain amplifier to amplify the second signal in accordance with second characteristics, output the second signal amplified to a second amplification element, the second variable gain amplifier having the second characteristics whose gain corresponding to the control signal is expressed by a second sigmoid function; and a characteristics adjuster to adjust a gain of the first sigmoid function or a gain of the second sigmoid function depending on target signal frequency.

### CROSS REFERENCE TO RELATED APPLICATION

This application is a Continuation of PCT International Application No. PCT/JP2023/025807, filed on Jul. 13, 2023, which is hereby expressly incorporated by reference into the present application.

### TECHNICAL FIELD

The present disclosure relates to a variable gain amplification device and a two-input amplification device.

### BACKGROUND ART

There is a variable gain amplification device that includes a splitter that splits an amplification target signal into two signals, and outputs the one split signal and the other split signal, a first variable gain amplifier that amplifies the one split signal and outputs the one amplified signal to a first amplification element, and a second variable gain amplifier that amplifies the other split signal and outputs the other amplified signal to a second amplification element.

As such a variable gain amplification device, for example, Patent Literature 1 discloses a variable gain amplification device in which each of a first variable gain amplifier and a second variable gain amplifier has variable gain characteristics that a gain corresponding to a control signal indicating the magnitude of an envelope of an amplification target signal is expressed by a sigmoid function to implement a highly efficient operation. The variable gain amplification device includes adjustment means for adjusting variable gain characteristics to achieve a wider band of an amplification target signal. Adjustment of the variable gain characteristics includes adjustment of a gain range of the variable gain characteristics, and adjustment of sliding a curve indicating the variable gain characteristics.

### CITATION LIST

### Patent Literature

Patent Literature 1: JP H2-100406 A

### SUMMARY OF INVENTION

### Technical Problem

The variable gain amplification device disclosed in Patent Literature 1 has a problem in that the variable gain amplification device cannot obtain variable gain characteristics for implementing a highly efficient operation depending on the frequency of an amplification target signal even when adjusting a gain range or the like of the variable gain characteristics.

The present disclosure has been made to solve the above problem, and an object of the present disclosure is to provide a variable gain amplification device that can achieve a wider band of an amplification target signal than that of the variable gain amplification device disclosed in Patent Literature 1.

### Solution to Problem

A variable gain amplification device according to the present disclosure includes: a splitter to split an amplification target signal into two signals, and output one signal and the other signal which are included in the two signals; a first variable gain amplifier to amplify the one signal in accordance with first variable gain characteristics, and output the one signal amplified to a first amplification element, the first variable gain amplifier having the first variable gain characteristics whose gain corresponding to a control signal indicating a magnitude of an envelope of the amplification target signal is expressed by a first sigmoid function; a second variable gain amplifier to amplify the other signal in accordance with second variable gain characteristics, and output the other signal amplified to a second amplification element, the second variable gain amplifier having the second variable gain characteristics whose gain corresponding to the control signal is expressed by a second sigmoid function; and a characteristics adjuster to adjust one or more gains among a gain of the first sigmoid function and a gain of the second sigmoid function depending on a frequency of the amplification target signal.

### Advantageous Effects of Invention

According to the present disclosure, it is possible to achieve a wider band of an amplification target signal than that of a variable gain amplification device disclosed in Patent Literature 1.

### BRIEF DESCRIPTION OF DRAWINGS

FIG. 1 is a configuration diagram illustrating a two-input amplification device including a variable gain amplification device 4 according to Embodiment 1.

FIG. 2 is an explanatory view illustrating how a gain of a first variable gain amplifier 12 with respect to a control signal x changes when a coefficient k₁ of a first sigmoid function f₁(x) is adjusted.

FIG. 3 is an explanatory view illustrating how the gain of the first variable gain amplifier 12 with respect to the control signal x changes when a coefficient k₂ of the first sigmoid function f₁(x) is adjusted.

FIG. 4 is an explanatory view illustrating how the gain of the first variable gain amplifier 12 with respect to the control signal x changes when a coefficient k₃ of the first sigmoid function f₁(x) is adjusted.

FIG. 5 is an explanatory view illustrating how the gain of the first variable gain amplifier 12 with respect to the control signal x changes when a coefficient k₄ of the first sigmoid function f₁(x) is adjusted.

FIG. 6 is a configuration diagram illustrating the inside of the first variable gain amplifier 12 of the variable gain amplification device 4 according to Embodiment 1.

FIG. 7 is a configuration diagram illustrating the inside of a first variable gain amplifier 12 of a variable gain amplification device 4 according to Embodiment 2.

FIG. 8 is a configuration diagram illustrating the inside of a first variable gain amplifier 12 of a variable gain amplification device 4 according to Embodiment 3.

FIG. 9 is a configuration diagram illustrating the inside of a first variable gain amplifier 12 of a variable gain amplification device 4 according to Embodiment 4.

### DESCRIPTION OF EMBODIMENTS

Hereinafter, modes for carrying out the present disclosure will be described with reference to the accompanying drawings to describe the present disclosure in more detail.

### Embodiment 1

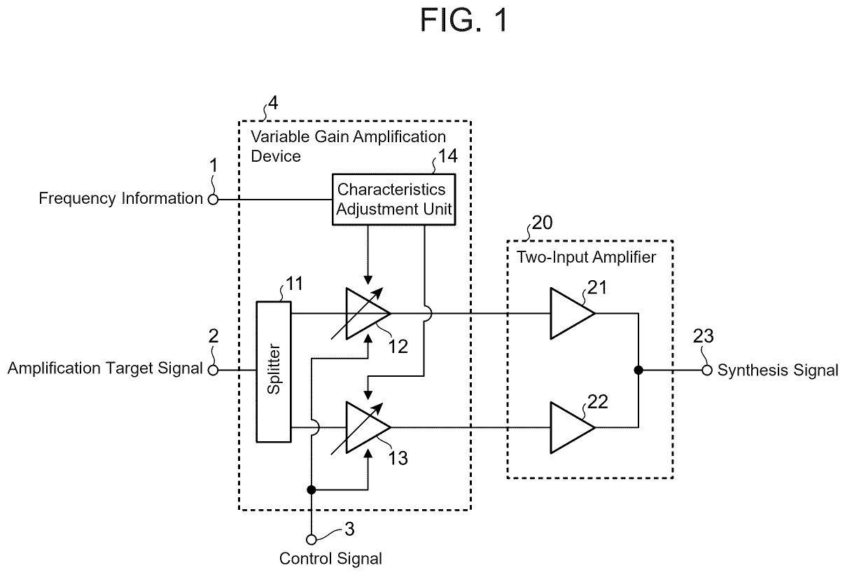

FIG. 1 is a configuration diagram illustrating a two-input amplification device including a variable gain amplification device 4 according to Embodiment 1.

The two-input amplification device illustrated in FIG. 1 includes the variable gain amplification device 4 and a two-input amplifier 20.

The variable gain amplification device 4 includes a splitter 11, a first variable gain amplifier 12, a second variable gain amplifier 13, and a characteristics adjustment unit 14.

The two-input amplifier 20 includes a first amplification element 21 and a second amplification element 22.

An input terminal 1 receives frequency information indicating the frequency of an amplification target signal from an outside.

An input terminal 2 receives the amplification target signal from the outside.

An input terminal 3 receives a control target signal from the outside. The control signal indicates the magnitude of an envelope of the amplification target signal given to the input terminal 2.

The splitter 11 splits the amplification target signal given to the input terminal 2 into two signals.

The splitter 11 outputs the one signal of the two split signals to the first variable gain amplifier 12, and outputs the other signal to the second variable gain amplifier 13.

The first variable gain amplifier 12 has first variable gain characteristics whose gain corresponding to a control signal is expressed by a first sigmoid function.

The first variable gain amplifier 12 amplifies the one signal output from the splitter 11 in accordance with the first variable gain characteristics, and outputs the one amplified signal to the first amplification element 21.

The second variable gain amplifier 13 amplifies the other signal output from the splitter 11 in accordance with second variable gain characteristics, and outputs the other amplified signal to the second amplification element.

An amplitude ratio that is a ratio of the amplitude of the one signal output from the splitter 11 to the first variable gain amplifier 12 and the amplitude of the other signal output from the splitter 11 to the second variable gain amplifier 13 is also expressed by a sigmoid function.

The characteristics adjustment unit 14 acquires the frequency information given to the input terminal 1.

The characteristics adjustment unit 14 adjusts one or more gains among a gain of the first sigmoid function indicating the first variable gain characteristics of the first variable gain amplifier 12, and a gain of the second sigmoid function indicating the second variable gain characteristics of the second variable gain amplifier 13 depending on the frequency of the amplification target signal indicated by the frequency information.

Although it is sufficient that the characteristics adjustment unit 14 adjusts one or more gains among the gain of the first sigmoid function and the gain of the second sigmoid function, the characteristics adjustment unit 14 may adjust each gain.

The variable gain amplification device 4 illustrated in FIG. 1 will be described assuming that the characteristics adjustment unit 14 adjusts each gain.

The first amplification element 21 amplifies the one signal amplified by the first variable gain amplifier 12.

The second amplification element 22 amplifies the other signal amplified by the second variable gain amplifier 13.

A synthesis signal of the one signal amplified by the first amplification element 21 and the other signal amplified by the second amplification element 22 is output to an output terminal 23.

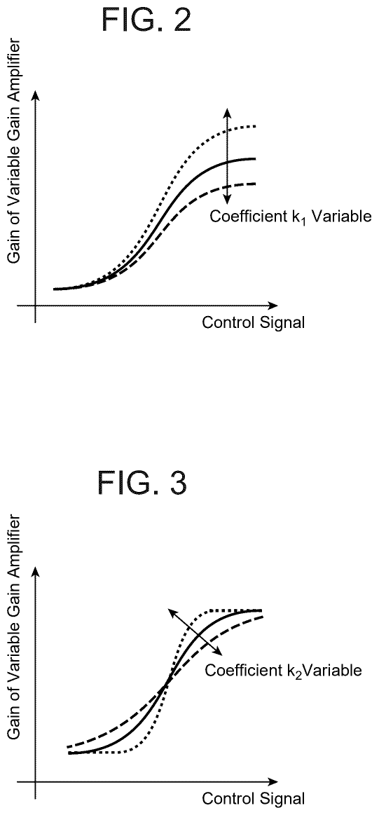

FIG. 2 is an explanatory view illustrating how a gain of the first variable gain amplifier 12 with respect to a control signal x changes when a coefficient k₁ of a first sigmoid function f₁(x) expressed in the following equation (1) is adjusted.

The first sigmoid function f₁(x) is a function indicating that an amplitude P₁ of the signal given to the first variable gain amplifier 12 changes depending on the control signal x. Adjustment of the coefficient k₁ of the first sigmoid function f₁(x) corresponds to adjustment of a gain range of the first variable gain characteristics.

FIG. 3 is an explanatory view illustrating how the gain of the first variable gain amplifier 12 with respect to the control signal x changes when a coefficient k₂ of the first sigmoid function f₁(x) expressed in the following equation (1) is adjusted. Adjustment of the coefficient k₂ of the first sigmoid function f₁(x) corresponds to adjustment of the gain of the first sigmoid function f₁(x).

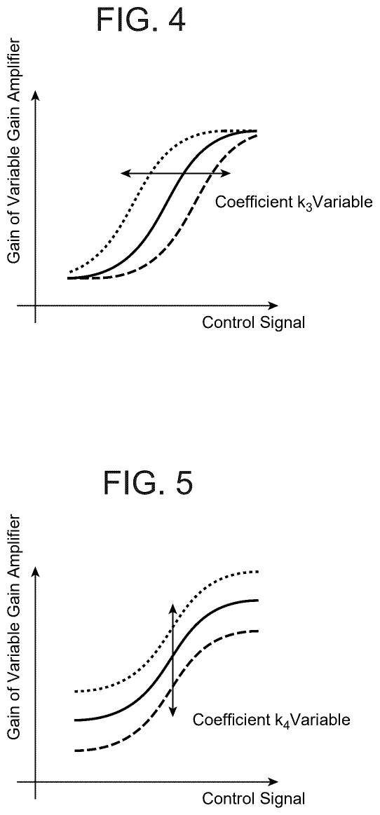

FIG. 4 is an explanatory view illustrating how the gain of the first variable gain amplifier 12 with respect to the control signal x changes when a coefficient k₃ of the first sigmoid function f₁(x) expressed in the following equation (1) is adjusted. Adjustment of the coefficient k₃ of the first sigmoid function f₁(x) corresponds to adjustment of sliding a curve indicating the first variable gain characteristics.

FIG. 5 is an explanatory view illustrating how the gain of the first variable gain amplifier 12 with respect to the control signal x changes when a coefficient k₄ of the first sigmoid function f₁(x) expressed in the following equation (1) is adjusted. Adjustment of the coefficient k₄ of the first sigmoid function f₁(x) corresponds to adjustment of sliding a curve indicating the first variable gain characteristics.

FIGS. 2 to 5 illustrate change in the gain of the first variable gain amplifier 12, and change in the gain of the second variable gain amplifier 13 is also illustrated as illustrated in FIGS. 2 to 5. The second sigmoid function f₂(x) indicating that an amplitude P₂ of the signal given to the second variable gain amplifier 13 changes depending on the control signal x is expressed as in the following equation (2).

Furthermore, an amplitude ratio R that is a ratio of the amplitude P₁ of the signal given from the splitter 11 to the first variable gain amplifier 12 and the amplitude P₂ of the signal given from the splitter 11 to the second variable gain amplifier 13 is also expressed by a sigmoid function as expressed in the following equation (3).

$${P}_{1} = {f}_{1} ( x ) G \cdot {P}_{in} = ( \frac{{k}_{1}}{1 + exp ( - ( {k}_{2} x - {k}_{3} ) )} + {k}_{4} ) G \cdot {P}_{in} \qquad ( 1 )$$

$${P}_{2} = {f}_{2} ( x ) G \cdot {P}_{in} = ( \frac{- {k}_{1}}{1 + exp ( - ( {k}_{2} x - {k}_{3} ) )} + 1 - {k}_{4} ) G \cdot {P}_{in} \qquad ( 2 )$$

$$R = \frac{{P}_{1}}{{P}_{1} + {P}_{2}} = \frac{{f}_{1} ( x )}{{f}_{1} ( x ) + {f}_{2} ( x )} \qquad ( 3 )$$

$${P}_{in} = {P}_{1} + {P}_{2} \qquad ( 4 )$$

In the equations (1) to (4), G represents an overall gain of the first variable gain amplifier 12 and the second variable gain amplifier 13, and Pin represents an amplitude of an amplification target signal given to the input terminal 2.

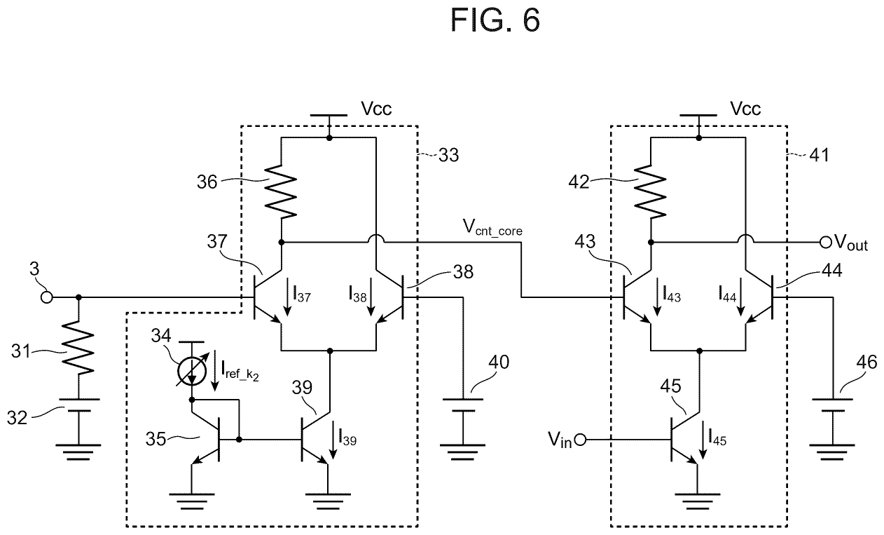

FIG. 6 is a configuration diagram illustrating the inside of the first variable gain amplifier 12 of the variable gain amplification device 4 according to Embodiment 1. The inside of the second variable gain amplifier 13 is the same as the inside of the first variable gain amplifier 12, and therefore a configuration diagram illustrating the inside of the second variable gain amplifier 13 will be omitted.

The first variable gain amplifier 12 includes a resistor 31, a power supply 32, a first control signal amplifier 33, a power supply 40, a first amplification target signal amplifier 41, and a power supply 46.

In a case of the second variable gain amplifier 13, the first control signal amplifier 33 illustrated in FIG. 6 is a second control signal amplifier, and the first amplification target signal amplifier 41 illustrated in FIG. 6 is a second amplification target signal amplifier.

The first control signal amplifier 33 includes a variable current source circuit 34, a transistor 35, a resistor 36, and transistors 37, 38, and 39.

The first amplification target signal amplifier 41 includes a resistor 42 and transistors 43, 44, and 45.

The one end of the resistor 31 is connected with each of the input terminal 3 and a base terminal of the transistor 37.

The other end of the resistor 31 is connected with a positive side of the power supply 32.

The positive side of the power supply 32 is connected with the other end of the resistor 31.

A negative side of the power supply 32 is connected with a ground.

The first control signal amplifier 33 amplifies a control signal on the basis of the coefficient k₂ adjusted by the characteristics adjustment unit 14, and outputs the amplified control signal to the first amplification target signal amplifier 41.

The variable current source circuit 34 outputs a current I_{ref_k2} corresponding to the coefficient k₂ adjusted by the characteristics adjustment unit 14 to each of a collector terminal and a base terminal of the transistor 35.

The collector terminal of the transistor 35 is connected with each of an output side of the variable current source circuit 34, the base terminal of the transistor 35, and a base terminal of the transistor 39.

An emitter terminal of the transistor 35 is connected with ground.

The base terminal of the transistor 35 is connected with each of the output side of the variable current source circuit 34, the collector terminal of the transistor 35, and the base terminal of the transistor 39.

The one end of the resistor 36 is applied with a voltage Vcc.

The other end of the resistor 36 is connected with each of a collector terminal of the transistor 37 and a base terminal of the transistor 43.

The base terminal of the transistor 37 is connected with each of the input terminal 3 and the one end of the resistor 31.

The collector terminal of the transistor 37 is connected with each of the other end of the resistor 36 and the base terminal of the transistor 43.

An emitter terminal of the transistor 37 is connected with each of an emitter terminal of the transistor 38 and a collector terminal of the transistor 39.

A base terminal of the transistor 38 is connected with the positive side of the power supply 40.

A collector terminal of the transistor 38 is applied with the voltage Vcc.

The emitter terminal of the transistor 38 is connected with each of the emitter terminal of the transistor 37 and the collector terminal of the transistor 39.

The base terminal of the transistor 39 is connected with each of the base terminal of the transistor 35, the collector terminal of the transistor 35, and the output side of the variable current source circuit 34.

The collector terminal of the transistor 39 is connected with each of the emitter terminal of the transistor 37 and the emitter terminal of the transistor 38.

An emitter terminal of the transistor 39 is connected with ground.

The first amplification target signal amplifier 41 amplifies the one signal output from the splitter 11 in accordance with the gain corresponding to the control signal amplified by the first control signal amplifier 33, and outputs the one amplified signal to the first amplification element 21.

The one end of the resistor 42 is applied with the voltage Vcc.

The other end of the resistor 42 is connected with each of a collector terminal of the transistor 43 and an output terminal Vₒᵤₜ.

The base terminal of the transistor 43 is connected with each of the other end of the resistor 36 and the collector terminal of the transistor 37.

The collector terminal of the transistor 43 is connected with each of the other end of the resistor 42 and the output terminal Vₒᵤₜ.

An emitter terminal of the transistor 43 is connected with each of the emitter terminal of the transistor 44 and the collector terminal of the transistor 45.

A base terminal of the transistor 44 is connected with the positive side of the power supply 46.

A collector terminal of the transistor 44 is applied with the voltage Vcc.

The emitter terminal of the transistor 44 is connected with each of the emitter terminal of the transistor 43 and the collector terminal of the transistor 45.

A base terminal of the transistor 45 is connected with an input terminal Vᵢₙ. The input terminal Vᵢₙ receives the one signal output from the splitter 11.

The collector terminal of the transistor 45 is connected with each of the emitter terminal of the transistor 43 and the emitter terminal of the transistor 44.

An emitter terminal of the transistor 45 is connected with ground.

The positive side of the power supply 46 is connected with the base terminal of the transistor 44.

The negative side of the power supply 46 is connected with ground.

Next, an operation of the two-input amplification device illustrated in FIG. 1 will be described.

The splitter 11 acquires an amplification target signal given to the input terminal 2.

The splitter 11 splits the amplification target signal into two signals.

The splitter 11 outputs the one signal of the two split signals to the first variable gain amplifier 12, and outputs the other signal to the second variable gain amplifier 13.

When receiving the one signal from the splitter 11, the first variable gain amplifier 12 amplifies the one signal in accordance with the first variable gain characteristics, and outputs the one amplified signal to the first amplification element 21.

When receiving the other signal from the splitter 11, the second variable gain amplifier 13 amplifies the other signal in accordance with the second variable gain characteristics, and outputs the other amplified signal to the second amplification element 22.

The characteristics adjustment unit 14 acquires the frequency information given to the input terminal 1.

The characteristics adjustment unit 14 adjusts a gain of the first sigmoid function f₁(x) indicating the first variable gain characteristics of the first variable gain amplifier 12 depending on the frequency of the amplification target signal indicated by the frequency information.

Furthermore, the characteristics adjustment unit 14 adjusts a gain of the second sigmoid function f₂(x) indicating the second variable gain characteristics of the second variable gain amplifier 13 depending on the frequency of the amplification target signal indicated by the frequency information.

The variable gain amplification device disclosed in Patent Literature 1 includes adjustment means for adjusting each of the coefficients k₁, k₃, and k₄ of the sigmoid function indicating variable gain characteristics. However, the adjustment means cannot adjust the coefficient k₂ of the sigmoid function. Furthermore, the adjustment means cannot simultaneously adjust all of the coefficients k₁, k₃, and k₄ of the sigmoid function.

Hereinafter, gain adjustment of the first sigmoid function f₁(x) performed by the characteristics adjustment unit 14 will be described. Note that gain adjustment of the second sigmoid function f₂(x) performed by the characteristics adjustment unit 14 is the same as the gain adjustment of the first sigmoid function f₁(x), and therefore description thereof will be omitted.

In, for example, an internal memory of the characteristics adjustment unit 14, the current I_{ref_k2} corresponding to the coefficient k₂ of the first sigmoid function f₁(x) and the current I_{ref_k2} corresponding to the coefficient k₂ of the second sigmoid function f₂(x) are stored.

A current I₃₉ flowing from the collector terminal to the emitter terminal of the transistor 39 is determined depending on the current I_{ref_k2} output from the variable current source circuit 34 since the transistor 35 and the transistor 39 constitute a current mirror. The current I₃₉ is a sum of a current I₃₇ flowing from the collector terminal to the emitter terminal of the transistor 37, and a current I₃₈ flowing from the collector terminal to the emitter terminal of the transistor 38. Hence, the current I₃₉ is expressed as in the following equation (5).

$${I}_{39} = {I}_{37} + {I}_{38} \qquad ( 5 )$$

A voltage difference between a base voltage of the transistor 37 and a base voltage of a transistor 38 is determined depending on Vent that is a control signal given to the input terminal 3, and each of the current I₃₇ and the current I₃₈ changes in accordance with change of Vent.

While each of the current I₃₇ and the current I₃₈ changes in accordance with the change of Vent, the current I₃₉ is constant even when Vent changes.

Next, when the characteristics adjustment unit 14 changes the current I_{ref_k2}, the current I₃₇ also changes. The current I₃₇ changes substantially linearly when an absolute value of Vent is small. An inclination of linear characteristics of the current I₃₇ changes depending on the current I_{ref_k2}. That is, the inclination of the linear characteristics of the current I₃₇ changes depending on the coefficient k₂.

When the current I₃₇ flows through the resistor 36, a voltage V_{cnt_core} is applied to the base terminal of the transistor 43. The voltage V_{cnt_core} in a case where the absolute value of voltage V_{cnt} is small is expressed as in the following equation (6).

The voltage V_{cnt_core} linearly changes depending on V_{cnt} as expressed in the equation (6), and an inclination of the voltage V_{cnt_core} changes depending on the current I_{ref_k2} as expressed in the equation (6).

$${V}_{cnt \_ core} ( {V}_{cnt} ) = - \frac{{R}_{L} \cdot β {I}_{ref \_ k 2}}{4} \cdot {V}_{cnt} + ( {V}_{CC} - \frac{{R}_{L} \cdot β {I}_{ref \_ k 2}}{2} ) \qquad ( 6 )$$

In the equation (6), R_{L} represents a resistance value of the resistor 36, and B represents a current mirror ratio of the transistor 35 and the transistor 39.

A voltage difference between the base voltage of the transistor 43 and the base voltage of the transistor 44 is determined depending on the voltage V_{cnt_core}, and each of a current I₄₃ and a current I₄₄ changes in accordance with change of the voltage V_{cnt_core}.

A signal given to the input terminal Vᵢₙ is split to the transistor 43 and the transistor 44. Since the collector terminal of the transistor 44 is short-circuited, the signal split toward the transistor 44 side is not output from the output terminal Vₒᵤₜ. Accordingly, the signal to be output from the output terminal Vₒᵤₜ is a signal split toward the transistor 43 side.

Here, the signal passing through the transistor 43 is amplified in proportion to the magnitude of the current flowing through the transistor 43, the current being determined depending on an inter-base terminal voltage V_{cnt_rf}. The inter-base terminal voltage V_{cnt_rf} is a voltage difference between the base voltage of the transistor 43 and the base voltage of the transistor 44. Hence, the amplitude P₁(=G_{rf}(V_{cnt_rf})) of the first variable gain amplifier 12 is expressed as in the following equation (7). G_{rf} represents a gain of the first variable gain amplifier 12.

$${P}_{1} = {G}_{rf} ( {V}_{cnt \_ rf} ) = \frac{{R}_{L} \cdot {g}_{1}}{1 + exp ( - ( {V}_{cnt \_ rf} / {V}_{T} ) )} \qquad ( 7 )$$

$${V}_{T} = \frac{kT}{q} \qquad ( 8 )$$

In the equation (7) and the equation (8), g₁ represents a transconductance of the transistor 45, V_{T} represents a thermal voltage, k represents a Boltzmann constant, T represents an absolute temperature, and q represents electronic charge.

The equation (7) shows that the first variable gain characteristics of the first variable gain amplifier 12 become the sigmoid function by changing the inter-base terminal voltage V_{cnt_rf}.

Here, the inclination of linear characteristics of the inter-base terminal voltage V_{cnt_rf} with respect to V_{cnt} changes depending on the current I_{ref_k2}.

When the absolute value of V_{cnt} is small, the first control signal amplifier 33 linearly amplifies V_{cnt} in accordance with amplification factor—R_{L}*βI_{ref_k2}/4. Hence, the amplitude P₁ expressed in the equation (7) is expressed as in the following equation (9).

$${P}_{1} = {G}_{rf} ( {V}_{cnt} ) = \frac{{R}_{L} \cdot {g}_{1}}{1 + exp ( - ( - \frac{{R}_{L} \cdot β {I}_{ref \_ k 2}}{4} \cdot {V}_{cnt} / {V}_{T} ) )} \qquad ( 9 )$$

Consequently, the characteristics adjustment unit 14 adjusts the coefficient k₂ of the first sigmoid function f₁(x), so that it is possible to adjust the gain of the first variable gain characteristics of the first variable gain amplifier 12.

That is, when V_{cnt} that is the control signal is given to the input terminal 3, the characteristics adjustment unit 14 adjusts the current I_{ref_k2} corresponding to the coefficient k₂ of the first sigmoid function f₁(x) in such a way that, as illustrated in FIG. 3, the gain of the first variable gain amplifier 12 corresponding to the frequency of the amplification target signal is a desired gain. The characteristics adjustment unit 14 controls the variable current source circuit 34 to adjust the current I_{ref_k2}.

The first amplification element 21 amplifies the one amplified signal when receiving the one signal amplified by the first variable gain amplifier 12.

The second amplification element 22 amplifies the other amplified signal when receiving the other signal amplified by the second variable gain amplifier 13.

A synthesis signal of the one signal amplified by the first amplification element 21 and the other signal amplified by the second amplification element 22 is output from the output terminal 23.

According to above Embodiment 1, the variable gain amplification device 4 includes: the splitter 11 that splits an amplification target signal into two signals, and outputs the one split signal and the other split signal, the first variable gain amplifier 12 that has the first variable gain characteristics whose gain corresponding to the control signal indicating the magnitude of the envelope of the amplification target signal is expressed by the first sigmoid function, amplifies the one signal in accordance with the first variable gain characteristics, and outputs the one amplified signal to the first amplification element 21, and the second variable gain amplifier 13 that has the second variable gain characteristics whose gain corresponding to the control signal is expressed by the second sigmoid function, amplifies the other signal in accordance with the second variable gain characteristics, and outputs the other amplified signal to the second amplification element 22. Furthermore, the variable gain amplification device 4 includes the characteristics adjustment unit 14 that adjusts one or more gains among the gain of the first sigmoid function and the gain of the second sigmoid function depending on the frequency of the amplification target signal. Consequently, the variable gain amplification device 4 can achieve a wider band of the amplification target signal than that of the variable gain amplification device disclosed in Patent Literature 1.

### Embodiment 2

Embodiment 2 will describe a variable gain amplification device 4 in which a characteristics adjustment unit 14 adjusts the coefficient k₂ of the first and second sigmoid functions and, in addition, adjusts the coefficient k₁ of the first and second sigmoid functions.

The configuration of a two-input amplification device including the variable gain amplification device 4 according to Embodiment 2 is the same as the configuration of the two-input amplification device including the variable gain amplification device 4 according to Embodiment 1, and a configuration diagram illustrating the two-input amplification device including the variable gain amplification device 4 according to Embodiment 2 is FIG. 1.

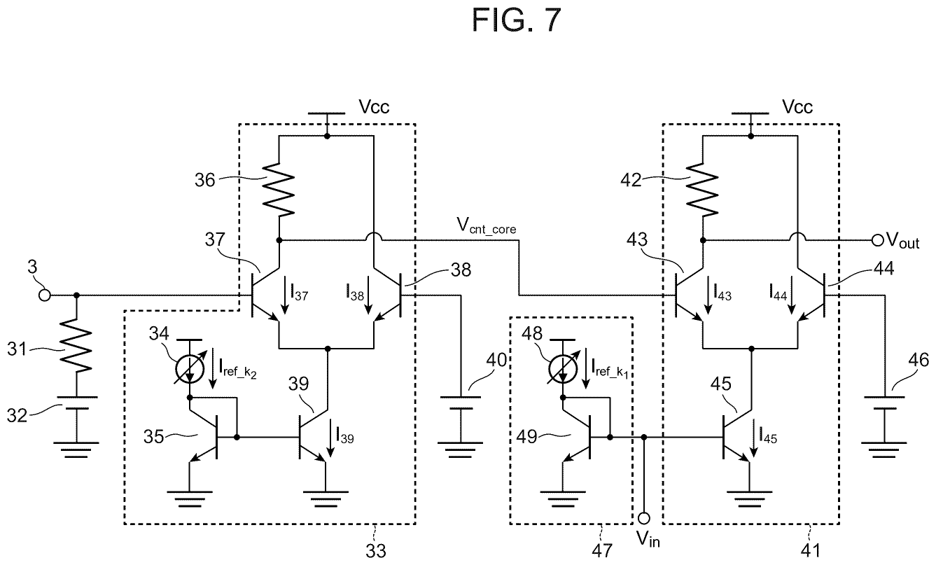

FIG. 7 is a configuration diagram illustrating the inside of a first variable gain amplifier 12 of the variable gain amplification device 4 according to Embodiment 2. Note that, in FIG. 7, the same reference numerals as those in FIG. 6 indicate identical or corresponding parts, and therefore detailed description thereof will be omitted.

The inside of a second variable gain amplifier 13 is the same as the inside of the first variable gain amplifier 12, and therefore the configuration diagram illustrating the inside of the second variable gain amplifier 13 will be omitted.

The first variable gain amplifier 12 includes the resistor 31, the power supply 32, the first control signal amplifier 33, the power supply 40, the first amplification target signal amplifier 41, the power supply 46, and a first gain adjustment circuit 47.

In a case of the second variable gain amplifier 13, the first gain adjustment circuit 47 illustrated in FIG. 7 is the second gain adjustment circuit.

The first gain adjustment circuit 47 includes a variable current source circuit 48 and a transistor 49.

The first gain adjustment circuit 47 adjusts the amplitude of a control signal amplified by the first control signal amplifier 33 on the basis of the coefficient k₁ adjusted by the characteristics adjustment unit 14. The coefficient k₁ is a coefficient for adjusting the gain range of the first variable gain characteristics.

The variable current source circuit 48 outputs a current I_{ref_k1} corresponding to the coefficient k₁ adjusted by the characteristics adjustment unit 14 to a collector terminal and a base terminal of the transistor 49.

The collector terminal of the transistor 49 is connected with each of an output side of the variable current source circuit 48, the base terminal of the transistor 49, the base terminal of the transistor 45, and Vᵢₙ.

An emitter terminal of the transistor 49 is connected with ground.

The base terminal of the transistor 49 is connected with each of the output side of the variable current source circuit 48, the collector terminal of the transistor 49, the base terminal of the transistor 45, and Vᵢₙ.

Next, an operation of the two-input amplification device according to Embodiment 2 will be described. In this regard, since the components other than the characteristics adjustment unit 14 and the first gain adjustment circuit 47 are the same as those of the two-input amplification device according to Embodiment 1, operations of the characteristics adjustment unit 14 and the first gain adjustment circuit 47 will be mainly described hereinafter.

In, for example, an internal memory of the characteristics adjustment unit 14, each of the current I_{ref_k2} corresponding to the coefficient k₂ of the first sigmoid function f₁(x) and the current I_{ref_k1} corresponding to the coefficient k₁ of the first sigmoid function f₁(x) is stored.

Furthermore, in an internal memory of the characteristics adjustment unit 14, each of the current I_{ref_k2} corresponding to the coefficient k₂ of the second sigmoid function f₂(x) and the current I_{ref_k1} corresponding to the coefficient k₁ of the second sigmoid function f₂(x) is stored.

A current I₄₅ flowing from the collector terminal to the emitter terminal of the transistor 45 is determined depending on the current I_{ref_k1} output from the variable current source circuit 48 since the transistor 45 and the transistor 49 constitute a current mirror. The current I₄₅ is a sum of the current I₄₃ flowing from the collector terminal to the emitter terminal of the transistor 43, and the current I₄₄ flowing from the collector terminal to the emitter terminal of the transistor 44. Hence, the current I₄₅ is expressed as in the following equation (10).

$${I}_{45} = {I}_{43} + {I}_{44} \qquad ( 10 )$$

A voltage difference between the base voltage of the transistor 43 and the base voltage of the transistor 44 is determined depending on the voltage V_{cnt_core}, and each of the current I₄₃ and the current I₄₄ changes in accordance with the change of V_{cnt_core}.

While each of the current I₄₃ and the current I₄₄ changes in accordance with the change of V_{cnt_core}, the current I₄₅ is constant even when the voltage V_{cnt_core} changes.

Next, when the characteristics adjustment unit 14 changes the current I_{ref_k1}, the current I₄₃ also changes. The current I₄₃ changes substantially linearly when an absolute value of V_{cnt_core} is small. An inclination of linear characteristics of the current I₄₃ changes depending on the current I_{ref_k1}. That is, the inclination of the linear characteristics of the current I₄₃ changes depending on the coefficient k₁.

More specifically, when V_{cnt} that is the control signal is given to the input terminal 3, the characteristics adjustment unit 14 adjusts the current I_{ref_k1} corresponding to the coefficient k₁ of the first sigmoid function f₁(x) in such a way that, as illustrated in FIG. 2, the amplitude P₁ of the first variable gain amplifier 12 corresponding to the frequency of the amplification target signal is a desired amplitude. The characteristics adjustment unit 14 controls the variable current source circuit 48 to adjust the current I_{ref_k1}.

When the current I_{ref_k1} is adjusted, the amplitude P₁ expressed in the equation (7) is expressed as in the following equation (11).

$${P}_{1} = {G}_{rf} ( {V}_{cnt} ) = \frac{{R}_{L} \cdot {g}_{1} ( {I}_{ref \_ k 1} )}{1 + exp ( - ( - \frac{{R}_{L} \cdot β {I}_{ref \_ k 2}}{4} \cdot {V}_{cnt} / {V}_{T} ) )} \qquad ( 11 )$$

According to above Embodiment 2, the variable gain amplification device 4 is configured in such a way that the first variable gain amplifier 12 further includes the first gain adjustment circuit 47 that adjusts the amplitude of the control signal amplified by the first control signal amplifier 33 on the basis of the coefficient k₁ of the first sigmoid function adjusted by the characteristics adjustment unit 14, and the second variable gain amplifier 13 further includes the second gain adjustment circuit that adjusts the amplitude of the control signal amplified by the second control signal amplifier on the basis of the coefficient k₁ of the second sigmoid function adjusted by the characteristics adjustment unit 14. Consequently, the variable gain amplification device 4 according to Embodiment 2 can achieve a wider band of the amplification target signal than that of the variable gain amplification device 4 according to Embodiment 1.

### Embodiment 3

Embodiment 3 will describe a variable gain amplification device 4 in which a characteristics adjustment unit 14 adjusts the coefficients k₁ and k₂ of the first and second sigmoid functions and, in addition, adjusts the coefficient k₃ of the first and second sigmoid functions.

The configuration of a two-input amplification device including the variable gain amplification device 4 according to Embodiment 3 is the same as the configuration of the two-input amplification device including the variable gain amplification device 4 according to Embodiment 1 or the configuration of the two-input amplification device including the variable gain amplification device 4 according to Embodiment 2. Hence, a configuration diagram illustrating the two-input amplification device including the variable gain amplification device 4 according to Embodiment 3 is FIG. 1.

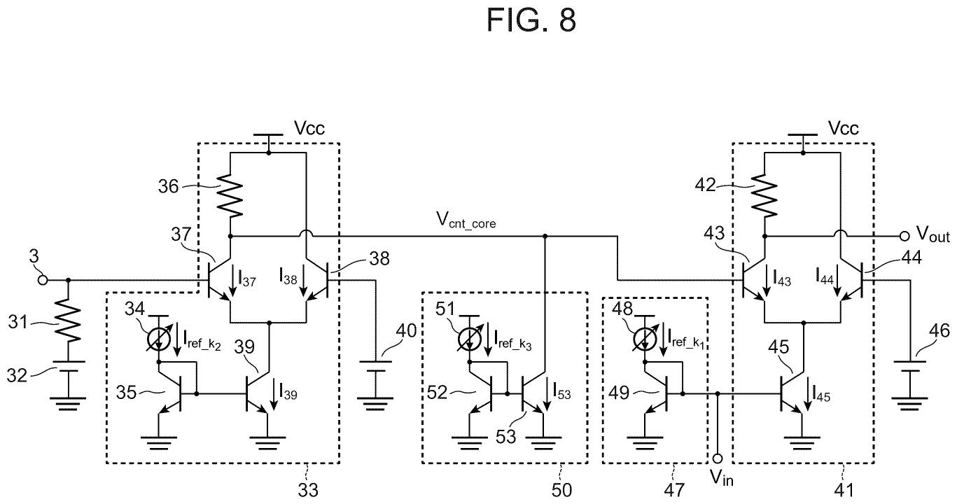

FIG. 8 is a configuration diagram illustrating the inside of a first variable gain amplifier 12 of the variable gain amplification device 4 according to Embodiment 3. Note that, in FIG. 8, the same reference numerals as those in FIGS. 6 and 7 indicate identical or corresponding parts, and therefore detailed description thereof will be omitted.

The inside of a second variable gain amplifier 13 is the same as the inside of the first variable gain amplifier 12, and therefore the configuration diagram illustrating the inside of the second variable gain amplifier 13 will be omitted.

The first variable gain amplifier 12 includes the resistor 31, the power supply 32, the first control signal amplifier 33, the power supply 40, the first amplification target signal amplifier 41, the power supply 46, the first gain adjustment circuit 47, and a first offset adder circuit 50.

In the case of the second variable gain amplifier 13, the first offset adder circuit 50 illustrated in FIG. 8 is a second offset adder circuit.

The first variable gain amplifier 12 illustrated in FIG. 8 is configured by applying the first offset adder circuit 50 to the first variable gain amplifier 12 illustrated in FIG. 7. However, this is merely an example, and the first variable gain amplifier 12 may be configured by applying the first offset adder circuit 50 to the first variable gain amplifier 12 illustrated in FIG. 6.

The first offset adder circuit 50 includes a variable current source circuit 51, a transistor 52, and a transistor 53.

The first offset adder circuit 50 adds an offset to a control signal amplified by the first control signal amplifier 33 on the basis of the coefficient k₃ adjusted by the characteristics adjustment unit 14. The coefficient k₃ is a coefficient for adjustment of sliding a curve indicating the first variable gain characteristics. More specifically, the coefficient k₃ is the coefficient for offsetting the first variable gain characteristics in a horizontal axis direction in FIG. 4.

The variable current source circuit 51 outputs a current I_{ref_k3} corresponding to the coefficient k₃ adjusted by the characteristics adjustment unit 14 to a collector terminal and a base terminal of the transistor 52.

The collector terminal of the transistor 52 is connected with each of an output side of the variable current source circuit 51, the base terminal of the transistor 52, and a base terminal of the transistor 53.

An emitter terminal of the transistor 52 is connected with ground.

The base terminal of the transistor 52 is connected with each of the output side of the variable current source circuit 48, the collector terminal of the transistor 52, and the base terminal of the transistor 53.

The base terminal of the transistor 53 is connected with each of the base terminal of the transistor 52, the collector terminal of the transistor 52, and the output side of the variable current source circuit 51.

A collector terminal of the transistor 53 is connected with each of the collector terminal of the transistor 37, the other end of the resistor 36, and the base terminal of the transistor 43.

An emitter terminal of the transistor 53 is connected with ground.

Next, an operation of the two-input amplification device according to Embodiment 3 will be described. In this regard, since the components other than the characteristics adjustment unit 14 and the first offset adder circuit 50 are the same as those of the two-input amplification device according to Embodiment 2, operations of the characteristics adjustment unit 14 and the first offset adder circuit 50 will be mainly described hereinafter.

In, for example, an internal memory of the characteristics adjustment unit 14, each of the current I_{ref_k2} corresponding to the coefficient k₂ of the first sigmoid function f₁(x), the current I_{ref_k1} corresponding to the coefficient k₁ of the first sigmoid function f₁(x), and the current I_{ref_k3} corresponding to the coefficient k₃ of the first sigmoid function f₁(x) is stored.

Furthermore, in the internal memory of the characteristics adjustment unit 14, each of the current I_{ref_k2} corresponding to the coefficient k₂ of the second sigmoid function f₂(x), the current I_{ref_k1} corresponding to the coefficient k₁ of the second sigmoid function f₂(x), and the current I_{ref_k3} corresponding to the coefficient k₃ of the second sigmoid function f₂(x) is stored.

A current I₅₃ flowing from the collector terminal to the emitter terminal of the transistor 53 is determined depending on the current I_{ref_k3} output from the variable current source circuit 51 since the transistor 52 and the transistor 53 constitute a current mirror.

Hence, when the characteristics adjustment unit 14 changes the current I_{ref_k3}, the current I₅₃ changes. When the current I₅₃ changes, the voltage V_{cnt_core} is offset. When the voltage V_{cnt_core} is offset depending on the change of the current I₅₃, the amplitude P₁ expressed in the equation (7) is expressed as in the following equation (12).

$${P}_{1} = {G}_{rf} ( {V}_{cnt} ) = \frac{{R}_{L} \cdot {g}_{1} ( {I}_{ref \_ k 1} )}{1 + exp ( - \frac{{R}_{L}}{{V}_{T}} \cdot ( - \frac{β {I}_{ref \_ k 2}}{4} {V}_{cnt} - γ {I}_{ref \_ k 3} ) )} \qquad ( 12 )$$

In the equation (12), γ represents a current mirror ratio of the transistor 52 and the transistor 53.

When V_{cnt} that is the control signal is given to the input terminal 3, the characteristics adjustment unit 14 adjusts the current I_{ref_k3} corresponding to the coefficient k₃ of the first sigmoid function f₁(x) in such a way that, as illustrated in FIG. 4, the gain of the first variable gain amplifier 12 corresponding to the frequency of the amplification target signal is a desired gain. The characteristics adjustment unit 14 controls the variable current source circuit 51 to adjust the current I_{ref_k3}.

According to above Embodiment 3, the variable gain amplification device 4 is configured in such a way that the first variable gain amplifier 12 further includes the first offset adder circuit 50 that adds an offset to the control signal amplified by the first control signal amplifier 33 on the basis of the coefficient k₃ adjusted by the characteristics adjustment unit 14, and the second variable gain amplifier 13 further includes the second offset adder circuit that adds an offset to the control signal amplified by the second control signal amplifier on the basis of the coefficient k₃ adjusted by the characteristics adjustment unit 14. Consequently, the variable gain amplification device 4 according to Embodiment 3 can achieve a wider band of the amplification target signal than those of the variable gain amplification devices 4 according to Embodiments 1 and 2.

### Embodiment 4

Embodiment 4 will describe a variable gain amplification device 4 in which a characteristics adjustment unit 14 adjusts the coefficients k₁, k₂, and k₃ of the first and second sigmoid functions and, in addition, adjusts the coefficient k₄ of the first and second sigmoid functions.

The configuration of a two-input amplification device including the variable gain amplification device 4 according to Embodiment 4 is the same as the configuration of the two-input amplification device including the variable gain amplification device 4 according to Embodiment 1, the configuration of the two-input amplification device including the variable gain amplification device 4 according to Embodiment 2, or the configuration of the two-input amplification device including the variable gain amplification device 4 according to Embodiment 3. Hence, a configuration diagram illustrating the two-input amplification device including the variable gain amplification device 4 according to Embodiment 4 is FIG. 1.

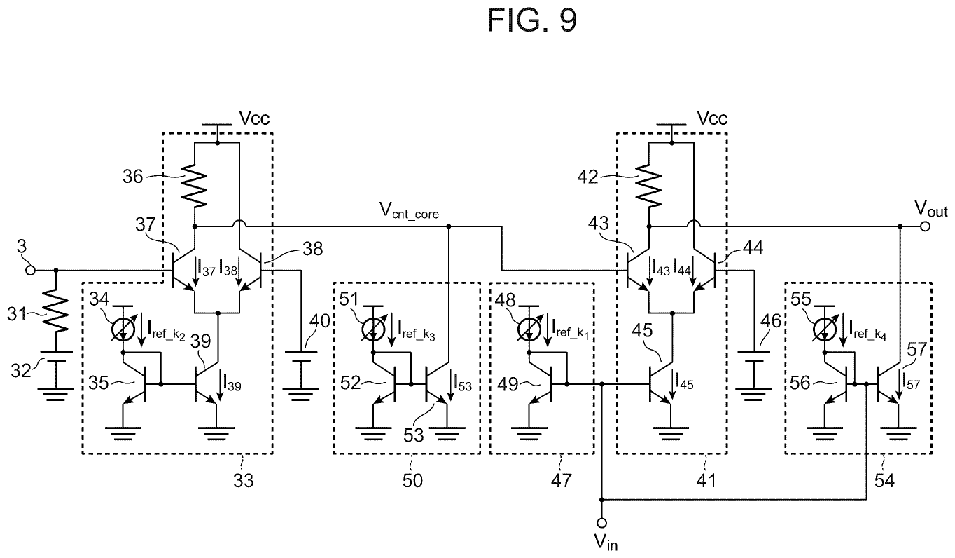

FIG. 9 is a configuration diagram illustrating the inside of a first variable gain amplifier 12 of the variable gain amplification device 4 according to Embodiment 4. Note that, in FIG. 9, the same reference numerals as those in FIGS. 6, 7, and 8 indicate identical or corresponding parts, and therefore detailed description thereof will be omitted.

The inside of a second variable gain amplifier 13 is the same as the inside of the first variable gain amplifier 12, and therefore the configuration diagram illustrating the inside of the second variable gain amplifier 13 will be omitted.

The first variable gain amplifier 12 includes the resistor 31, the power supply 32, the first control signal amplifier 33, the power supply 40, the first amplification target signal amplifier 41, the power supply 46, the first gain adjustment circuit 47, the first offset adder circuit 50, and a third offset adder circuit 54.

In the case of the second variable gain amplifier 13, the third offset adder circuit 54 illustrated in FIG. 9 is a fourth offset adder circuit.

The first variable gain amplifier 12 illustrated in FIG. 9 is configured by applying the third offset adder circuit 54 to the first variable gain amplifier 12 illustrated in FIG. 8. However, this is merely an example, and the first variable gain amplifier 12 may be configured by applying the third offset adder circuit 54 to the first variable gain amplifier 12 illustrated in FIG. 6 or to the first variable gain amplifier 12 illustrated in FIG. 7.

The third offset adder circuit 54 includes a variable current source circuit 55, a transistor 56, and a transistor 57.

The third offset adder circuit 54 adds an offset to a signal amplified by the first amplification target signal amplifier 41 on the basis of the coefficient k₄ adjusted by the characteristics adjustment unit 14. The coefficient k₄ is a coefficient for adjustment of sliding a curve indicating the first variable gain characteristics. More specifically, the coefficient k₄ is the coefficient for offsetting the first variable gain characteristics in a vertical axis direction in FIG. 5.

The variable current source circuit 55 outputs a current I_{ref_k4} corresponding to the coefficient k₄ adjusted by the characteristics adjustment unit 14 to each of a collector terminal and a base terminal of the transistor 56.

The collector terminal of the transistor 56 is connected with each of an output side of the variable current source circuit 55, the base terminal of the transistor 56, and a base terminal of the transistor 57.

An emitter terminal of the transistor 56 is connected with ground.

The base terminal of the transistor 56 is connected with each of the output side of the variable current source circuit 55, the collector terminal of the transistor 56, and the base terminal of the transistor 56.

The base terminal of the transistor 57 is connected with each of the base terminal of the transistor 56, the collector terminal of the transistor 56, and the output side of the variable current source circuit 55.

A collector terminal of the transistor 57 is connected with each of the collector terminal of the transistor 43, the other end of the resistor 42, and the output terminal Vₒᵤₜ.

An emitter terminal of the transistor 57 is connected with ground.

Next, an operation of the two-input amplification device according to Embodiment 4 will be described. In this regard, since the components other than the characteristics adjustment unit 14 and the third offset adder circuit 54 are the same as those of the two-input amplification device according to Embodiment 3, operations of the characteristics adjustment unit 14 and the third offset adder circuit 54 will be mainly described hereinafter.

In, for example, the internal memory of the characteristics adjustment unit 14, each of the current I_{ref_k2} corresponding to the coefficient k₂ of the first sigmoid function f₁(x), the current I_{ref_k1} corresponding to the coefficient k₁ of the first sigmoid function f₁(x), the current I_{ref_k3} corresponding to the coefficient k₃ of the first sigmoid function f₁(x), and the current I_{ref_k4} corresponding to the coefficient k₄ of the first sigmoid function f₁(x) is stored.

Furthermore, in an internal memory of the characteristics adjustment unit 14, each of the current I_{ref_k2} corresponding to the coefficient k₂ of the second sigmoid function f₂(x), the current I_{ref_k1} corresponding to the coefficient k₁ of the second sigmoid function f₂(x), the current I_{ref_k3} corresponding to the coefficient k₃ of the second sigmoid function f₂(x), and the current I_{ref_k4} corresponding to the coefficient k₄ of the second sigmoid function f₂(x) is stored.

A current I₅₇ flowing from the collector terminal to the emitter terminal of the transistor 57 is determined depending on the current I_{ref_k4} output from the variable current source circuit 55 since the transistor 56 and the transistor 57 constitute a current mirror.

Hence, when the characteristics adjustment unit 14 changes the current I_{ref_k4}, the current I₅₇ changes. When the current I₅₇ changes, the voltage output from the output terminal Vₒᵤₜ is offset.

When the voltage V_{cnt_core} is offset depending on the change of the current I₅₇, the amplitude P₁ expressed in the equation (7) is expressed as in the following equation (13).

$${P}_{1} = {G}_{rf} ( {V}_{cnt} ) = \frac{{R}_{L} \cdot {g}_{1} ( {I}_{ref \_ k 1} )}{1 + exp ( - \frac{{R}_{L}}{{V}_{T}} \cdot ( - \frac{β {I}_{ref \_ k 2}}{4} {V}_{cnt} - γ {I}_{ref \_ k 3} ) )} + {g}_{11} ( {t}_{ref \_ k 4} ) \qquad ( 13 )$$

In the equation (13), g₁₁ represents a gain of the third offset adder circuit 54.

When V_{cnt} that is the control signal is given to the input terminal 3, the characteristics adjustment unit 14 adjusts the current I_{ref_k4} corresponding to the coefficient k₄ of the first sigmoid function f₁(x) in such a way that, as illustrated in FIG. 5, the gain of the first variable gain amplifier 12 corresponding to the frequency of the amplification target signal is a desired gain. The characteristics adjustment unit 14 controls the variable current source circuit 55 to adjust the current I_{ref_k4}.

According to above Embodiment 4, the variable gain amplification device 4 is configured in such a way that the first variable gain amplifier 12 further includes the third offset adder circuit 54 that adds an offset to the one signal amplified by the first amplification target signal amplifier 41 on the basis of the coefficient k₄ adjusted by the characteristics adjustment unit 14, and the second variable gain amplifier 13 further includes the fourth offset adder circuit that adds an offset to the other signal amplified by the second amplification target signal amplifier on the basis of the coefficient k₄ adjusted by the characteristics adjustment unit 14. Consequently, the variable gain amplification device 4 according to Embodiment 4 can achieve a wider band of the amplification target signal than those of the variable gain amplification devices 4 according to Embodiments 1 and 3.

Note that the present disclosure allows any combinations of the embodiments, any modification of components in the embodiments, or any omission of components in the embodiments.

### INDUSTRIAL APPLICABILITY

The present disclosure is suitable for a variable gain amplification device and a two-input amplification device.

### REFERENCE SIGNS LIST

1, 2, 3: input terminal, 4: variable gain amplification device, 11: splitter, 12: first variable gain amplifier, 13: second variable gain amplifier, 14: characteristics adjustment unit, 20: two-input amplifier, 21: first amplification element, 22: second amplification element, 23: output terminal, 31: resistor, 32: power supply, 33: first control signal amplifier, 34: variable current source circuit, 35: transistor, 36: resistor, 37, 38, 39: transistor, 40: power supply, 41: first amplification target signal amplifier, 42: resistor, 43, 44, 45: transistor, 46: power supply, 47: first gain adjustment circuit, 48: variable current source circuit, 49: transistor, 50: first offset adder circuit, 51: variable current source circuit, 52, 53: transistor, 54: third offset adder circuit, 55: variable current source circuit, 56: transistor, 57: transistor

1. A variable gain amplification device comprising:
a splitter to split an amplification target signal into two signals, and output one signal and an other signal which are included in the two signals;
a first variable gain amplifier to amplify the one signal in accordance with first variable gain characteristics, and output the one signal amplified to a first amplification element, the first variable gain amplifier having the first variable gain characteristics whose gain corresponding to a control signal indicating a magnitude of an envelope of the amplification target signal is expressed by a first sigmoid function;
a second variable gain amplifier to amplify the other signal in accordance with second variable gain characteristics, and output the other signal amplified to a second amplification element, the second variable gain amplifier having the second variable gain characteristics whose gain corresponding to the control signal is expressed by a second sigmoid function; and
a characteristics adjuster to adjust one or more gains among a gain of the first sigmoid function and a gain of the second sigmoid function depending on a frequency of the amplification target signal.

2. The variable gain amplification device according to claim 1, wherein the characteristics adjuster adjusts each of the gain of the first sigmoid function and the gain of the second sigmoid function depending on the frequency of the amplification target signal.

3. The variable gain amplification device according to claim 2, wherein
the first sigmoid function is f₁(x) and the second sigmoid function is f₂(x), and
the characteristics adjuster adjusts the gain of the first sigmoid function f₁(x) by adjusting a coefficient k₂ of the f₁(x), and adjusts the gain of the second sigmoid function f₂(x) by adjusting a coefficient k₂ of the f₂(x),
$${f}_{1} ( x ) = \frac{{k}_{1}}{1 + exp ( - ( {k}_{2} x - l {ι}_{3} ) )} + {k}_{4}$$
$${f}_{2} ( x ) = \frac{- {k}_{1}}{1 + exp ( - ( {k}_{2} x - {k}_{3} ) )} + 1 - {k}_{4}$$
where x represents the control signal, and each of k₁, k₂, k₃, and k₄ represents a coefficient of each of the first sigmoid function and the second sigmoid function.

4. The variable gain amplification device according to claim 3, wherein the characteristics adjuster adjusts each of the coefficient k₂ of the first sigmoid function and the coefficient k₂ of the second sigmoid function depending on the frequency of the amplification target signal, and, in addition, adjusts each of a coefficient k₁, a coefficient k₃, and a coefficient k₄ of the first sigmoid function and adjusts each of a coefficient k₁, a coefficient k₃, and a coefficient k₄ of the second sigmoid function.

5. The variable gain amplification device according to claim 4, wherein
the first variable gain amplifier includes
a first control signal amplifier to amplify a control signal given from an outside on a basis of the coefficient k₂ of the first sigmoid function adjusted by the characteristics adjuster, and
a first amplification target signal amplifier to amplify the one signal output from the splitter in accordance with the control signal amplified by the first control signal amplifier, and output the one signal amplified to the first amplification element, and
the second variable gain amplifier includes
a second control signal amplifier to amplify a control signal given from the outside on a basis of the coefficient k₂ of the second sigmoid function adjusted by the characteristics adjuster, and
a second amplification target signal amplifier to amplify the other signal output from the splitter in accordance with the control signal amplified by the second control signal amplifier, and output the other signal amplified to the second amplification element.

6. The variable gain amplification device according to claim 5, wherein
the first variable gain amplifier further includes a first gain adjustment circuit to adjust an amplitude of the control signal amplified by the first control signal amplifier on a basis of the coefficient k₁ of the first sigmoid function adjusted by the characteristics adjuster, and
the second variable gain amplifier further includes a second gain adjustment circuit to adjust an amplitude of the control signal amplified by the second control signal amplifier on a basis of the coefficient k₁ of the second sigmoid function adjusted by the characteristics adjuster.

7. The variable gain amplification device according to claim 5, wherein
the first variable gain amplifier further includes a first offset adder circuit to add an offset to the control signal amplified by the first control signal amplifier on a basis of the coefficient k₃ of the first sigmoid function adjusted by the characteristics adjuster, and
the second variable gain amplifier further includes a second offset adder circuit to add an offset to the control signal amplified by the second control signal amplifier on a basis of the coefficient k₃ of the second sigmoid function adjusted by the characteristics adjuster.

8. The variable gain amplification device according to claim 5, wherein
the first variable gain amplifier further includes a third offset adder circuit to add an offset to the one signal amplified by the first amplification target signal amplifier on a basis of the coefficient k₄ of the first sigmoid function adjusted by the characteristics adjuster, and
the second variable gain amplifier further includes a fourth offset adder circuit to add an offset to the other signal amplified by the second amplification target signal amplifier on a basis of the coefficient k₄ of the second sigmoid function adjusted by the characteristics adjuster.

9. A two-input amplification device comprising:
a splitter to split an amplification target signal into two signals, and output one signal and an other signal which are included in the two signals;
a first variable gain amplifier to amplify the one signal in accordance with first variable gain characteristics, the first variable gain amplifier having the first variable gain characteristics whose gain corresponding to a control signal indicating a magnitude of an envelope of the amplification target signal is expressed by a first sigmoid function;
a second variable gain amplifier to amplify the other signal in accordance with second variable gain characteristics, the second variable gain amplifier having the second variable gain characteristics whose gain corresponding to the control signal is expressed by a second sigmoid function;
a characteristics adjuster to adjust one or more gains among a gain of the first sigmoid function and a gain of the second sigmoid function depending on a frequency of the amplification target signal; and
a two-input amplifier to output a synthesis signal of one signal amplified by a first amplification element and an other signal amplified by a second amplification element, the two-input amplifier including the first amplification element to amplify the one signal amplified by the first variable gain amplifier, and the second amplification element to amplify the other signal amplified by the second variable gain amplifier.
